(19) United States
(12) Patent Application Publication
(10) Pub. No.: US 2012/0306028 A1
(43) Pub. Date: Dec. 6, 2012

(54) SEMICONDUCTOR PROCESS AND STRUCTURE THEREOF

(76) Inventors: Yu-Ren Wang, Tainan City (TW); Te-Lin Sun, Kaohsiung City (TW); Szu-Hao Lai, Kaohsiung City (TW); Po-Chun Chen, Tainan City (TW); Chih-Hsun Lin, Ping-Tung County (TW); Che-Nan Tsai, Tainan City (TW); Chun-Ling Lin, Tainan City (TW); Chiu-Hsien Yeh, Tainan City (TW); Chien-Liang Lin, Taoyuan County (TW); Shao-Wei Wang, Taichung City (TW); Ying-Wei Yen, Miaoli County (TW)

(21) Appl. No.: 13/118,561

(22) Filed: May 30, 2011

(51) Int. Cl. H01L 29/772; H01L 21/28

(52) U.S. Cl. 257/411; 438/591; 257/E21.19; 257/E29.242

(57) ABSTRACT

A semiconductor process is provided, including: a substrate is provided, a buffer layer is formed, and a dielectric layer having a high dielectric constant is formed, wherein the methods of forming the buffer layer include: (1) an oxidation process is performed; and a baking process is performed; Alternatively, (2) an oxidation process is performed; a thermal nitridation process is performed; and a plasma nitridation process is performed; Or, (3) a decoupled plasma oxidation process is performed. Furthermore, a semiconductor structure fabricated by the last process is also provided.

### BACKGROUND OF THE INVENTION

1. Field of the Invention

The present invention relates generally to a semiconductor process and structure thereof, and more specifically, to a semiconductor process and structure thereof capable of improving the performance of buffer layers.

2. Description of the Prior Art

Poly-silicon is conventionally used as a gate electrode in semiconductor devices, such as the metal-oxide-semiconductor (MOS). However, with a trend toward scaling down the size of semiconductor devices, the conventional poly-silicon gate has faced problems such as inferior performance due to boron penetration and unavoidable depletion effect which increases equivalent thickness of the gate dielectric layer, reduces gate capacitance, and worsens a driving force of the devices. Therefore, work function metals are used to replace the conventional poly-silicon gate as the control electrode suitable for use as the high-K gate dielectric layer.

Due to the extreme difference in material properties between a gate dielectric layer having a high dielectric constant and a substrate, at least a buffer layer is formed between the two in current processes for buffering. The buffer layer may be an oxide layer such as a silicon dioxide layer which is formed by performing an oxidation process on a silicon-containing substrate.

However, due to miniaturization and the demands of the semiconductor structure performance, improving the performance of the effective oxide layer (including the buffer layer and the dielectric layer having a high dielectric constant) located between the metal gate and the substrate has become an important issue in the industry. More specifically, fabricating methods capable of improving the effective oxide thickness (EOT) and Gate Oxide Leakage (Jg) of the effective oxide layer are issues that need to be addressed.

### SUMMARY OF THE INVENTION

The present invention provides one semiconductor process and structure thereof to improve the effective oxide layer, and more specifically, to improve the performance of the buffer layer included in the effective oxide layer, for reducing the effective oxide thickness (EOT) and Gate Oxide Leakage (Jg) of the effective oxide layer.

The present invention provides a semiconductor process. A substrate is provided. An oxidation process is performed to form an oxide layer on the surface of the substrate. A baking process is performed for reducing the thickness of the oxide layer. A dielectric layer having a high dielectric constant is formed on the oxide layer.

The present invention provides another semiconductor process. A substrate is provided. An oxidation process is performed to form an oxide layer on the surface of the substrate. A thermal nitridation process is performed to nitride the oxide layer. A plasma nitridation process is performed to nitride the oxide layer. A dielectric layer having a high dielectric constant is formed on the oxide layer.

The present invention provides another semiconductor process. A substrate is provided. A decoupled plasma oxidation process is performed to form an oxide layer on the surface of the substrate. A dielectric layer having a high dielectric constant is formed on the oxide layer.

The present invention provides a semiconductor structure, including a substrate, an oxide layer, a silicon-containing hafnium oxide layer and a hafnium oxide layer. The oxide layer is located on the surface of the substrate. The silicon-containing hafnium oxide layer is located on the oxide layer. The hafnium oxide layer is located on the silicon-containing hafnium oxide layer.

According to the above, the present invention provides a semiconductor process which includes the following steps: a substrate is provided, a buffer layer is formed, and a dielectric layer having a high dielectric constant is formed. The methods of forming the buffer layer include: (1) an oxidation process is performed and then a baking process is performed. Alternatively, (2) an oxidation process is performed, a thermal nitridation process is performed, and then a plasma nitridation process is performed. Or, (3) a decoupled plasma oxidation process is performed. Otherwise, a semiconductor structure formed by the method of (3) is also provided, which has a transition layer located between the oxide layer and the dielectric layer having a high dielectric constant. Therefore, the performances of semiconductor structures can be improved by enhancing the density of the oxide layer, nitriding the oxide layer or forming a transition layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a semiconductor process according to one embodiment of the present invention.

FIG. 2 schematically depicts an experimental data of a semiconductor process according to one embodiment of the present invention.

FIG. 3 schematically depicts a cross-sectional view of a semiconductor process according to one embodiment of the present invention.

FIG. 4 schematically depicts a cross-sectional view of a semiconductor process according to one embodiment of the present invention.

FIG. 5 schematically depicts a cross-sectional view of a MOS transistor applying gate-first process according to one embodiment of the present invention.

FIG. 6 schematically depicts a cross-sectional view of a MOS transistor applying gate-last process according to one embodiment of the present invention.

FIG. 7 schematically depicts a cross-sectional view of a MOS transistor applying gate-last for high-k first process according to one embodiment of the present invention.

FIG. 8 schematically depicts a cross-sectional view of a MOS transistor applying gate-last for high-k last and buffer layer-first process according to one embodiment of the present invention.

FIG. 9 schematically depicts a cross-sectional view of a MOS transistor applying gate-last for high-k last and buffer layer-last process according to one embodiment of the present invention.

### DETAILED DESCRIPTION

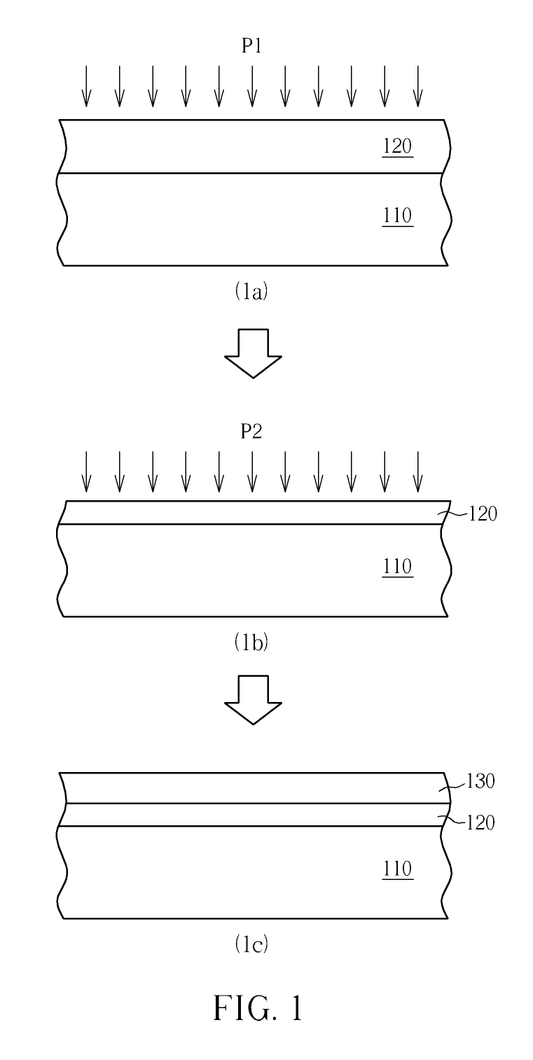

FIG. 1 schematically depicts a cross-sectional view of a semiconductor process according to one embodiment of the present invention. As shown in FIG. 1a, a substrate 110 is provided. An oxidation process P1 is performed on the substrate 110 to form an oxide layer 120 on the surface of the substrate 110. The substrate 110 may be a semiconductor substrate such as a silicon substrate, a silicon-containing substrate or a silicon-on-insulator (SOI) substrate. In this embodiment, the substrate 110 is a silicon substrate, so that the oxide layer 120 is a silicon dioxide layer formed by performing the oxidation process P1 to oxidize the silicon substrate, but it is not limited thereto. Otherwise, the oxidation process P1 may be a wet oxidation process such as an in situ steam generation (ISSG) oxidation process, a dry oxidation process etc. When the process temperature of the oxidation process P1 is high or the process time of the oxidation process P1 is long, an oxide layer 120 having a denser structure can be formed, thereby reducing the circuit leakage and avoiding the ingredients of the upper material layer diffusing downward, and thereby the performance of the oxide layer 120 is improved. However, when the temperature of the oxidation process P1 is too high, a self-consuming effect of the oxide layer 120 occurs, and the structure of the oxide layer 120 is damaged. Therefore, in a preferred embodiment, the process temperature of the oxidation process P1 is lower than the temperature of 1080° C. In a still preferred embodiment, the process temperature of the oxidation process P1 is at a temperature between 1000° C. and 1080° C. for increasing the density of the oxide layer 120 while avoiding the self-consuming effect.

As shown in FIG. 1b, a baking process P2 is performed on the oxide layer 120 to reduce the thickness of the oxide layer 120. In this embodiment, the baking process P2 is a hydrogen-containing or a deuterium-containing baking process and the process temperature of the baking process P2 is higher than 1000° C., thereby the purpose of reducing the thickness of the oxide layer 120 is achieved. In a preferred embodiment, the hydrogen-containing or deuterium-containing baking process is performed at a temperature between 1000° C. and 1100° C. In a still preferred embodiment, the hydrogen-containing or deuterium-containing baking process is performed at a temperature between 1050° C. and 1075° C. The reasons for the preferred process are: the self-consuming effect of the oxide layer 120 will occur when the process temperature of the baking process P2 is too high; that is, the self-consuming effect of the oxide layer 120 will occur even after the oxidation process P1 is performed. According to the above, restricting the process temperature of the baking process P2 not only reduces the thickness of the oxide layer 120, but also protects the structure of the oxide layer 120, thereby improving the performance of the oxide layer 120. Otherwise, performing the deuterium-containing baking process is better than performing the hydrogen-containing baking process because of the passivating characteristic of the deuterium, meaning broken bonds will not easily occur when the deuterium reacts with the oxide layer 120. Thereby, the structure of the oxide layer 120 can be more uniform.

As shown in FIG. 1c, a dielectric layer having a high dielectric constant 130 is formed on the oxide layer 120. The dielectric layer having a high dielectric constant 130 may be a metal containing dielectric layer, such as hafnium oxide, zirconium oxide, but is not limited thereto. Furthermore, the dielectric layer having a high dielectric constant 130 may be composed of hafnium oxide (HfO₂), zirconium oxide (ZrO₂), hafnium zirconium oxide (HfZrO), hafnium aluminum oxide (HfAlO), hafnium lanthanum oxide (HfLaO), hafnium silicon oxide (HfSiO), hafnium silicon oxynitride (HfSiON), aluminum oxide (AlO), lanthanum oxide (LaO), lanthanum aluminum oxide (LaAlO), tantalum oxide (TaO), zirconium oxide (ZrO), or zirconium silicon oxide (ZrSiO).

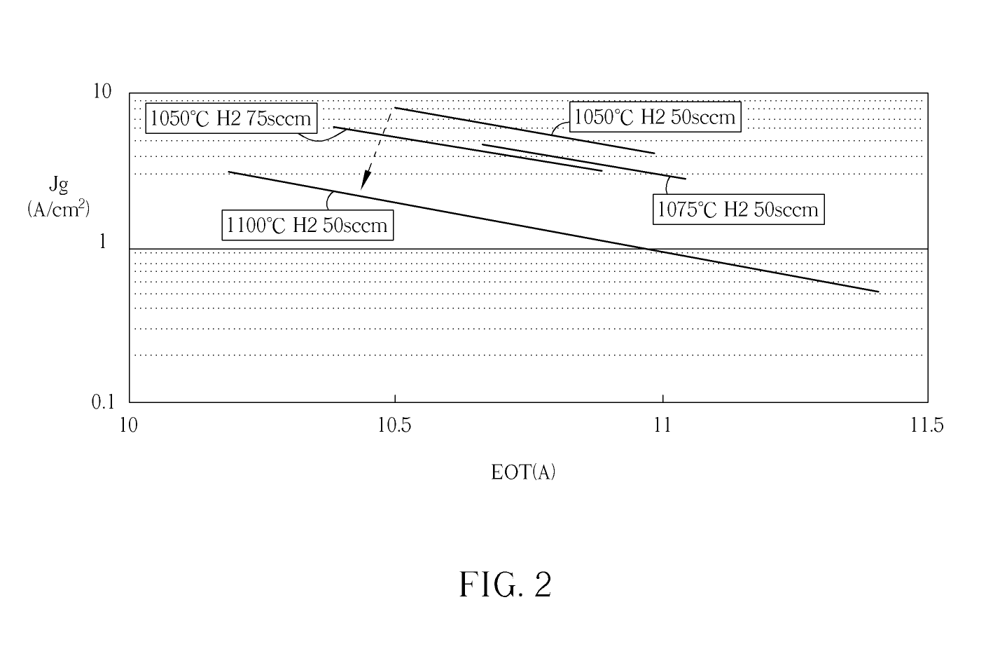

It is emphasized that oxide layer 120 is a buffer layer located between the dielectric layer having a high dielectric constant 130 and the substrate 110, and used for buffering the material properties difference between the dielectric layer having a high dielectric constant 130 and the substrate 120 and then improving the bonding quality. Used as a buffer layer, the effective oxide thickness (EOT) and the gate oxide leakage (Jg) of the oxide layer 120 can be reduced as the thickness of the oxide layer 120 is thinner and the structure of the oxide layer 120 is denser. Therefore, the oxidation process P1 is firstly performed to form the oxide layer 120 in the present invention, and then the baking process P2 is performed to thin the oxide layer 120. FIG. 2 schematically depicts an experimental data of a semiconductor process according to one embodiment of the present invention. Shown in FIG. 2 is the experimental result of performing the oxidation process P1 once and then performing the baking process P2 once, wherein the horizontal axis represents the effective oxide thickness, (EOT) and the vertical axis represents gate oxide leakage, (Jg). The purpose of the present invention is to let the effective oxide thickness (EOT) and the gate oxide leakage (Jg) be as small as possible, so that lines of FIG. 2 are preferably shifted left and down. As shown in FIG. 2, when the process temperature of the baking process is 1050° C. and the flow rate of importing hydrogen gas is 50 sccm (standard cubic centimeter per minute) and 75 sccm (standard cubic centimeter per minute), the line of 75 sccm shifts left and down more than the line of 50 sccm, therefore it can be concluded that the performance of the semiconductor structure is improved while the process temperature of the baking process increases. Furthermore, when the flow rate of importing hydrogen gas is 50 sccm and the process temperatures of the baking processes are 1050° C., 1075° C., and 1100° C., lines in FIG. 5 are shifted left and down as the process temperature increases, therefore the performance of the semiconductor structure is improved. It can be seen that desired semiconductor structures can be formed by adjusting the process temperature and the flow rate of importing hydrogen gas. Additionally, a denser structure of the oxide layer 120 can be formed and a desired thickness of the oxide layer 120 can also be achieved by performing the oxidation process P1 and the baking process P2 repeatedly. To sum up, the present invention can improve the performance of the semiconductor device by changing the process temperature of the baking process, changing the flow rate of importing gas, or changing the number of times of performing the oxidation process P1 and the baking process P2, so that the present invention has more flexibility in operations.

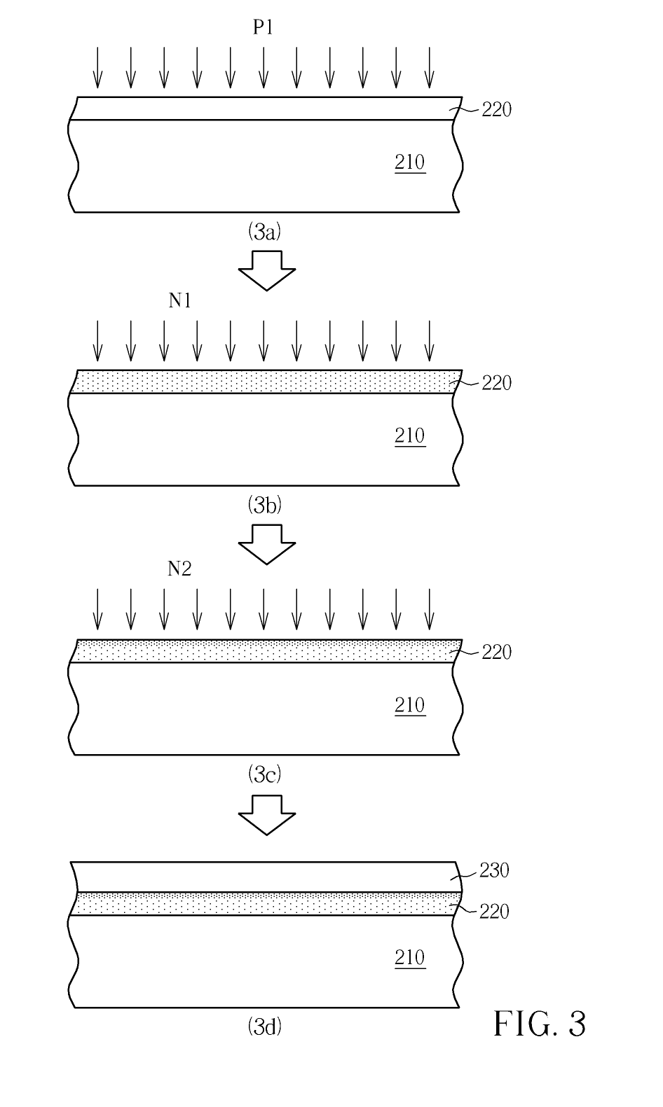

Otherwise, the present invention also provides another semiconductor process to reduce the effective oxide thickness (EOT) and gate oxide leakage (Jg), thereby enhancing the performance of the semiconductor structure. FIG. 3 schematically depicts a cross-sectional view of a semiconductor process according to one embodiment of the present invention. As shown in FIG. 3a, a substrate 210 is provided. An oxidation process P1 is performed to form an oxide layer 220 on the surface of the substrate 210. The substrate 210 may be a semiconductor substrate such as a silicon substrate, a silicon-containing substrate or a silicon-on-insulator (SOI) substrate. In this embodiment, the substrate 210 is a silicon substrate, so that the oxide layer 220 is a silicon dioxide layer formed by performing the oxidation process P1 to oxidize the silicon substrate, but it is not limited thereto. Otherwise, the oxidation process P1 may be a wet oxidation process such as an in situ steam generation (ISSG) oxidation process, a dry oxidation process etc. When the process temperature of the oxidation process P1 is higher or the process time of the oxidation process P1 is longer, the oxide layer 220 having a denser structure can be formed, thereby reducing the circuit leakage and avoiding the ingredients of the upper material layer diffusing downward, and thereby improving the performance of the oxide layer 220. However, when the process temperature of the oxidation process P1 is too high, a self-consuming effect of the oxide layer 220 occurs, and then the structure of the oxide layer 220 is damaged. Therefore, in a preferred embodiment, the process temperature of the oxidation process P1 is lower than the temperature of 1080° C. In a still preferred embodiment, the process temperature of the oxidation process P1 is at a temperature between 1000° C. and 1080° C. for increasing the density of the oxide layer 220 without having the self-consuming effect occur.

As shown in FIG. 3b, a thermal nitridation process N1 is performed to nitride the oxide layer 220. As shown in FIG. 3c, a plasma nitridation process N2 is performed to nitride the oxide layer 220. The nitriding area formed by the plasma nitridation process N2 concentrates on the surface of the oxide layer 220, but the thermal nitridation process N1 nitrides the whole oxide layer 220. The present invention applying two nitridation steps not only can increase the nitridation concentration of the oxide layer 220 to increase the dielectric constant of the oxide layer 220, but can also avoid nitrogen diffusing to the substrate 210, which affects the mobility of carriers in the channel beneath the oxide layer 220 and degrades the performance. This is because the nitridation concentration of the oxide layer 220 mainly concentrates on the upper surface of the oxide layer 220 and does not concentrate on the lower surface of the oxide layer 220 contacting the substrate 210. Furthermore, an annealing process (not shown) may be performed on the oxide layer 220 after the plasma nitridation process N2 is performed, wherein the annealing process (not shown) may be a post-nitridation annealing process, but is not limited thereto.

As shown in FIG. 3d, a dielectric layer having a high dielectric constant 230 is formed on the oxide layer 220. The dielectric layer having a high dielectric constant 230 may be a metal containing dielectric layer, such as hafnium oxide, zirconium oxide, but is not limited thereto. Furthermore, the dielectric layer having a high dielectric constant 230 may be composed of hafnium oxide (HfO₂), zirconium oxide (ZrO₂), hafnium zirconium oxide (HfZrO), hafnium aluminum oxide (HfAlO), hafnium lanthanum oxide (HfLaO), hafnium silicon oxide (HfSiO), hafnium silicon oxynitride (HfSiON), aluminum oxide (AlO), lanthanum oxide (LaO), lanthanum aluminum oxide (LaAlO), tantalum oxide (TaO), zirconium oxide (ZrO), or zirconium silicon oxide (ZrSiO).

According to the above two embodiments, other processes are performed to improve the performance of the oxide layer 120/220 after the oxidation process P1, so that the two embodiments can be combined together to further improve the performance of the oxide layer 120/220. For example, a substrate 110/210 is provided. An oxidation process P1 and a baking process P2 are sequentially performed. The oxidation process P1 and the baking process P2 can be performed repeatedly to achieve desired thickness of the oxide layer 120. Thereafter, a thermal nitridation process N1 and a plasma nitridation process N2 are sequentially performed. Then, an annealing process is selectively performed. A dielectric layer having a high dielectric constant 130/230 is formed on the oxide layer 220.

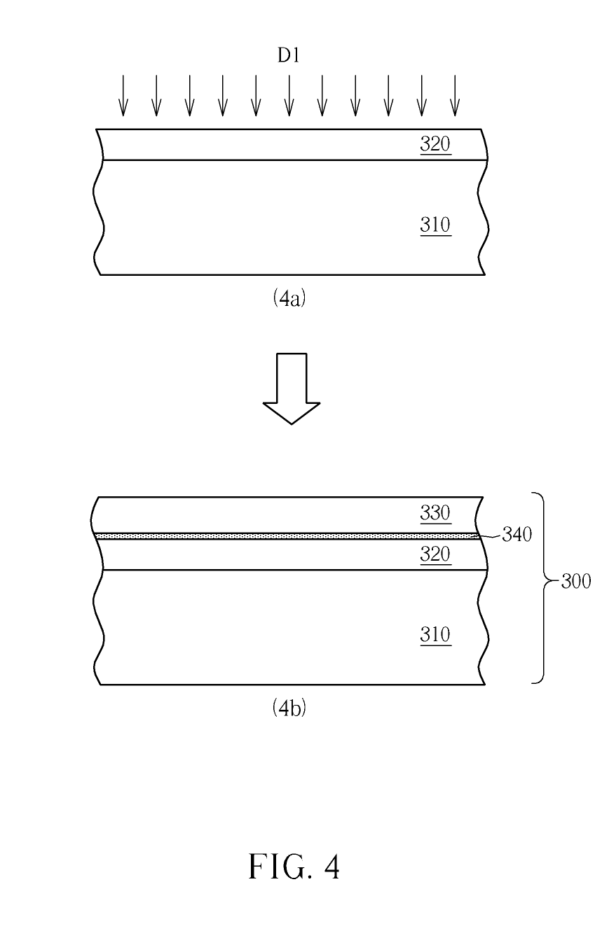

The present invention also provides still another semiconductor process to reduce the effective oxide thickness (EOT) and the gate oxide leakage (Jg) thereby enhancing the performance of the semiconductor structure. FIG. 4 schematically depicts a cross-sectional view of a semiconductor process according to one embodiment of the present invention. As shown in FIG. 4a, a substrate 310 is provided, wherein the substrate 310 may be a semiconductor substrate such as a silicon substrate, a silicon-containing substrate or a silicon-on-insulator (SOI) substrate. A decoupled plasma oxidation process D1 is performed to form an oxide layer 320 on the surface of the substrate 310. Furthermore, a treatment process (not shown) may be further performed after the decoupled plasma oxidation process D1 is performed to make the surface of the oxide layer 320 contain hydrogen-oxygen bonds, wherein the treatment process may be a pre-atomic layer deposition treatment process, and the pre-atomic layer deposition treatment process may be a 300s Standard clean 1 (SC1) process containing NH₄OH using for removing particles on the oxide layer 320, but is not limited thereto.

As shown in FIG. 4b, a dielectric layer having a high dielectric constant 330 is formed on the oxide layer 320, wherein the dielectric layer having a high dielectric constant 330 may be formed by the atomic layer deposition process (ALD), but is not limited thereto. The dielectric layer having a high dielectric constant 330 may be a metal containing dielectric layer, such as hafnium oxide, zirconium oxide, but is not limited thereto. Furthermore, the dielectric layer having a high dielectric constant 330 may be composed of hafnium oxide (HfO₂), zirconium oxide (ZrO₂), hafnium zirconium oxide (HfZrO), hafnium aluminum oxide (HfAlO), hafnium lanthanum oxide (HfLaO), hafnium silicon oxide (HfSiO), hafnium silicon oxynitride (HfSiON), aluminum oxide (AlO), lanthanum oxide (LaO), lanthanum aluminum oxide (LaAlO), tantalum oxide (TaO), zirconium oxide (ZrO), or zirconium silicon oxide (ZrSiO).

It should be noted that the oxidation process of the prior art is an oxidation process such as an in situ steam generation (ISSG) oxidation process. Its process temperature is between 850° C. and 1050° C., so that the oxide layer formed has a strong bonding structure compared to the oxide layer 320 of the present invention formed by the decoupled plasma oxidation process D1. In other words, the structure of the oxide layer 320 formed by the decoupled plasma oxidation process D1 has a weak bonding structure and this structure allows the ingredients of the dielectric layer having a high dielectric constant 330 formed on the oxide layer 320 to diffuse downward to the oxide layer 320, thereby a transition layer 340 is formed between the dielectric layer having a high dielectric constant 330 and the oxide layer 320. At this point, the structure of FIG. 4b is formed.

The semiconductor structure 300 of this embodiment may include a substrate 310, an oxide layer 320, a transition layer 340 and a dielectric layer having a high dielectric constant 330. The oxide layer 320 is located on the surface of the substrate 310. The transition layer 340 is located on the oxide layer 320. In this embodiment, the transition layer 340 is a silicon-containing hafnium oxide layer such as hafnium silicon oxide (HfSiO). The dielectric layer having a high dielectric constant 330 is located on the transition layer 340. In this embodiment, the dielectric layer having a high dielectric constant 330 is a hafnium oxide layer such as hafnium oxide (HfO₂). The transition layer 340 is formed while the dielectric layer having a high dielectric constant 330 is formed on the oxide layer 320. Due to the weak bonding structure of the oxide layer 320, the transition layer 340 can be formed between the oxide layer 320 and the dielectric layer having a high dielectric constant 330 by the ingredient diffusion of the dielectric layer having a high dielectric constant 330. Therefore, the present invention does not need to perform any other processes to form the transition layer 340.

In this way, because a portion of the oxide layer 320 transforms to the transition layer 340 having a higher dielectric constant than the oxide layer 320, the semiconductor structure 300 has a lower effective oxide thickness (EOT) than that of the prior art.

The above three embodiments of the present invention can be applied to various semiconductor devices. MOS transistors fabricated by gate first process and gate last process are provided in the following as examples, but the present invention can also be applied to other semiconductor processes, wherein gate last processes may include gate last process for high-k first, gate last process for high-k last and buffer layer first, and gate last process for high-k last and buffer layer last.

FIG. 5 schematically depicts a cross-sectional view of a MOS transistor applying gate-first process according to one embodiment of the present invention. As shown in FIG. 5, a substrate 410 is provided. Then, an oxide layer 420 and a dielectric layer having a high dielectric constant 430 can be formed by one of the semiconductor processes of the above three embodiments. Agate electrode layer 440 is formed on the dielectric layer having a high dielectric constant 430, wherein the gate electrode layer 440 may include a work function metal layer 442 and a main electrode layer 444 formed on the work function metal layer 442. Thereafter, the oxide layer 420, the dielectric layer having a high dielectric constant 430 and the gate electrode layer 440 are patterned; a spacer 450 is formed; and a drain/source region 460 is formed by an ion implantation process. A MOS transistor applying gate first process is now completed.

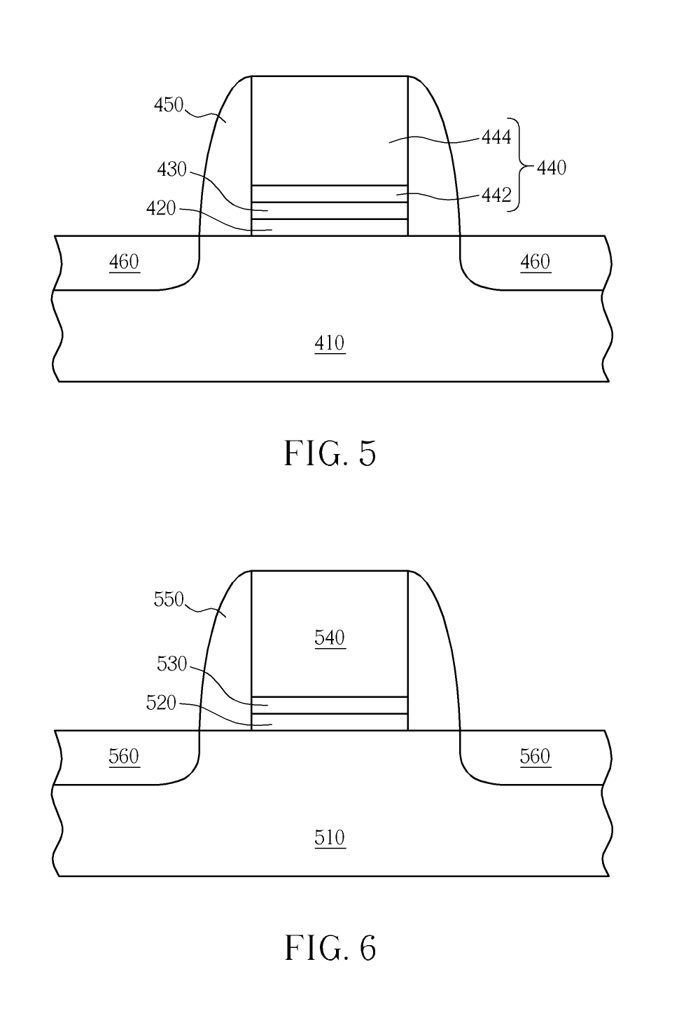

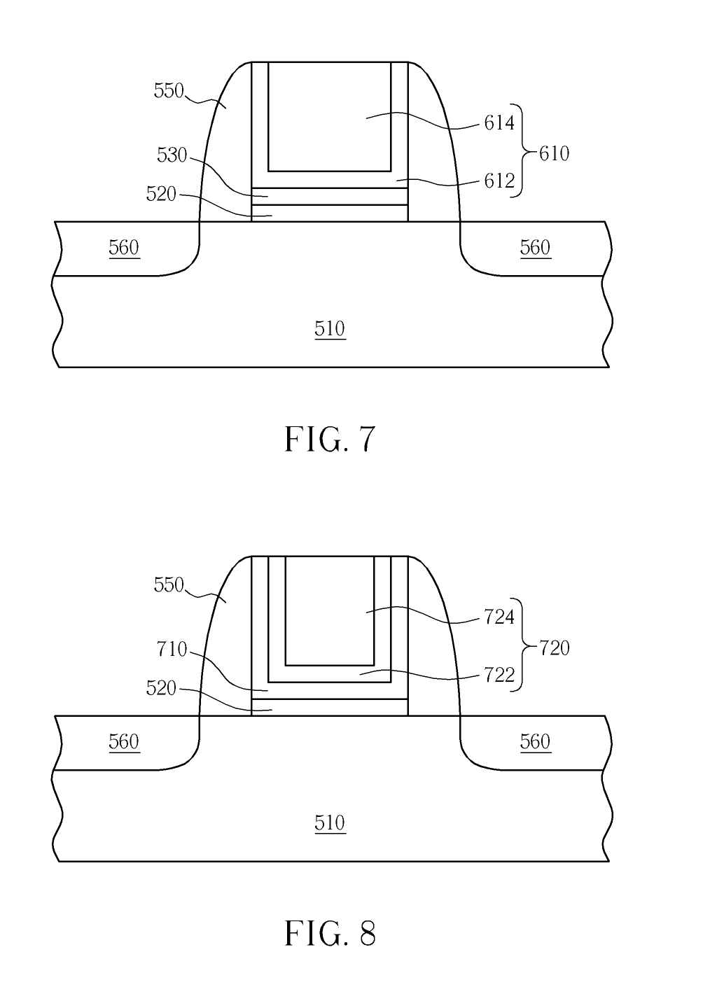

FIG. 6 schematically depicts a cross-sectional view of a MOS transistor applying gate-last process according to one embodiment of the present invention. FIG. 7 schematically depicts a cross-sectional view of a MOS transistor applying gate—last for high-k first process according to one embodiment of the present invention. As shown in FIG. 6, a substrate 510 is provided. An oxide layer, a dielectric layer and a sacrificed gate electrode layer are sequentially formed and patterned, so that an oxide layer 520, a dielectric layer 530 and a sacrificed gate electrode layer 540 are formed. In this embodiment, the oxide layer 520 and the dielectric layer 530 are sequentially formed by one of the semiconductor processes of the above three embodiments, so that the dielectric layer 530 is a dielectric layer having a high dielectric constant. Then, a spacer 550 is formed beside the sacrificed gate electrode layer 540, the dielectric layer 530 and the oxide layer 520. A source/drain region 560 is formed by an ion implantation process. As shown in FIG. 7, a sacrificed gate electrode layer 540 is removed and a metal gate 610 is filled. That is, the sacrificed gate electrode layer 540 is replaced with the metal gate 610, thereby the MOS transistor fabricated by gate last for high-k first process is finished, wherein the metal gate 610 may include a work function metal gate 612 and a main electrode 614 on the work function metal gate 612 and the work function metal gate 612 has a U-shaped cross-sectional profile.

FIG. 8 schematically depicts a cross-sectional view of a MOS transistor applying gate-last for high-k last and buffer layer-first process according to one embodiment of the present invention. Firstly, as shown in FIG. 6, a substrate 510 is provided. An oxide layer, a dielectric layer and a sacrificed gate electrode layer are sequentially formed and patterned to form an oxide layer 520, a dielectric layer 530 and a sacrificed gate electrode layer 540. In this embodiment, the oxide layer 520 is formed by one of the semiconductor processes of the above three embodiments and it should be noted that the dielectric layer 530 of this embodiment is a sacrificed gate dielectric layer so that it can be formed on the oxide layer 520 by any material without forming a dielectric layer having a high dielectric constant. Then, a spacer 550 is formed beside the sacrificed gate electrode layer 540, the dielectric layer 530 and the oxide layer 520. A source/drain region 560 is formed by an ion implantation process.

As shown in FIG. 8, the sacrificed gate electrode layer 540 and the dielectric layer 530 are removed to expose the oxide layer 520. A dielectric layer having a high dielectric constant 710 is formed on the oxide layer 520. A metal gate 720 is formed on the dielectric layer having a high dielectric constant 710, wherein the metal gate 720 may include a work function metal gate 722 and a main electrode 724 located on the work function metal gate 722. Therefore, the MOS transistor fabricated by gate last for high-k last and buffer layer first process is finished, wherein the dielectric layer having a high dielectric constant 710 and the work function metal gate 722 form a U-shaped cross-sectional profile.

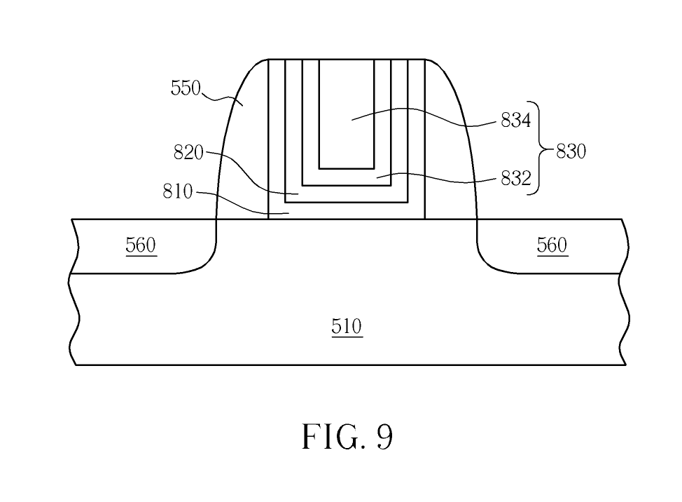

FIG. 9 schematically depicts a cross-sectional view of a MOS transistor applying gate—last for high-k last and buffer layer—last process according to one embodiment of the present invention. Firstly, as shown in FIG. 6, a substrate 510 is provided. An oxide layer, a dielectric layer and a sacrificed gate electrode layer are sequentially formed and patterned to form an oxide layer 520, a dielectric layer 530 and a sacrificed gate electrode layer 540. It should be noted that the oxide layer 520 of this embodiment is a sacrificed buffer layer and the dielectric layer 530 is a sacrificed gate dielectric layer, so that the present invention can provide a sacrificed buffer layer and sacrificed gate dielectric layer made of any material by forming them on the substrate 510 firstly. A spacer 550 is formed beside the sacrificed gate electrode layer 540, the dielectric layer 530 and the oxide layer 520.

As shown in FIG. 9, the sacrificed gate electrode layer 540, the dielectric layer 530 and the oxide layer 520 are removed to expose the substrate 510. The oxide layer 810 and the dielectric layer having a high dielectric constant 820 are formed by one of the semiconductor processes of the above three embodiments. A metal gate 830 is formed on the dielectric layer having a high dielectric constant 820, wherein the metal gate 830 may include a work function metal gate 832 and a main electrode 834 located on the work function metal gate 832. Therefore, the MOS transistor applying gate last for high-k last and buffer layer-last is completed, wherein the oxide layer 810, the dielectric layer having a high dielectric constant 820 and the work function metal gate 832 all have a U-shaped cross-sectional profile.

Above all, the present invention provides a semiconductor process including the following steps: a substrate is provided, a buffer layer is formed and a dielectric layer having a high dielectric constant is formed. The methods of forming the buffer layer may include: (1) an oxidation process is performed and then a baking process is performed. (2) an oxidation process is performed, a thermal nitridation process is performed, and then a plasma nitridation process is performed. Or, (3) a decoupled plasma oxidation process is performed. Moreover, the first two semiconductor processes can be combined together, so that the semiconductor process can include: a substrate is provided, an oxidation process is performed, a baking process is performed, a thermal nitridation process is performed, a plasma nitridation process is performed; and a dielectric layer having a high dielectric constant is formed. Otherwise, a semiconductor structure formed by the method of (3) is also provided, wherein a transition layer is located between the oxide layer and the dielectric layer has a high dielectric constant.

In this way, the higher dielectric constant, the lower effective oxide thickness (EOT) and the lower Gate Oxide Leakage (Jg) of the oxide layer can be obtained by enhancing the density of the oxide layer, nitriding the oxide layer or forming the transition layer between the oxide layer and the dielectric layer having a high dielectric constant, thereby the performance of the semiconductor structure is improved.

Those skilled in the art will readily observe that numerous modifications and alterations of the device and method may be made while retaining the teachings of the invention.

1. A semiconductor process, comprising:
providing a substrate;
performing an oxidation process to form an oxide layer on the surface of the substrate;
performing a baking process to reduce the thickness of the oxide layer; and
forming a dielectric layer having a high dielectric constant on the oxide layer.

2. The semiconductor process according to claim 1, wherein the steps of performing the oxidation process to form the oxide layer on the surface of the substrate and performing the baking process to reduce the thickness of the oxide layer are performed circularly for a plurality of times.

3. The semiconductor process according to claim 1, wherein the baking process comprises a hydrogen-containing or a deuterium-containing baking process.

4. The semiconductor process according to claim 3, wherein the temperature of the baking process is higher than 1000° C.

5. The semiconductor process according to claim 4, wherein the hydrogen-containing or the deuterium-containing baking process is performed at a temperature between 1000° C. and 1100° C.

6. The semiconductor process according to claim 5, wherein the hydrogen-containing or the deuterium-containing baking process is performed at a temperature between 1050° C. and 1075° C.

7. The semiconductor process according to claim 1, further comprising:
after forming the dielectric layer having a high dielectric constant on the oxide layer, forming a gate electrode layer on the dielectric layer having a high dielectric constant.

8. The semiconductor process according to claim 1, further comprising:
after forming the dielectric layer having a high dielectric constant on the oxide layer, forming a sacrificed gate electrode layer on the dielectric layer having a high dielectric constant;
patterning the oxide layer, the sacrificed gate electrode layer and the dielectric layer having a high dielectric constant;
forming a spacer beside the sacrificed gate electrode layer, the dielectric layer having a high dielectric constant and the oxide layer; and
replacing the sacrificed gate electrode layer with a metal gate.

9. The semiconductor process according to claim 1, further comprising:
after performing the baking process to thin the thickness of the oxide layer, forming a sacrificed gate dielectric layer on the oxide layer;
forming a sacrificed gate electrode layer on the sacrificed gate dielectric layer;
patterning the sacrificed gate electrode layer and the sacrificed gate dielectric layer;
forming a spacer beside the sacrificed gate electrode layer and the sacrificed gate dielectric layer; and
removing the sacrificed gate electrode layer and the sacrificed gate dielectric layer to expose the oxide layer.

10. The semiconductor process according to claim 9, further comprising:
after forming the dielectric layer having a high dielectric constant on the oxide layer, forming a metal gate on the dielectric layer having a high dielectric constant.

11. The semiconductor process according to claim 1, further comprising:
after providing the substrate, forming a sacrificed buffer layer on the substrate;
forming a sacrificed gate dielectric layer on the sacrificed buffer layer;
forming a sacrificed gate electrode layer on the sacrificed gate dielectric layer;
patterning the sacrificed gate electrode layer, the sacrificed gate dielectric layer and the sacrificed buffer layer;
forming a spacer beside the sacrificed gate electrode layer, the sacrificed gate dielectric layer and the sacrificed buffer layer; and
removing the sacrificed gate electrode layer, the sacrificed gate dielectric layer and the sacrificed buffer layer to expose the substrate.

12. The semiconductor process according to claim 11, further comprising:
after forming the dielectric layer having a high dielectric constant on the oxide layer,
forming a metal gate on the dielectric layer having a high dielectric constant.

13. The semiconductor process according to claim 1, further comprising:
after performing the baking process to thin the thickness of the oxide layer, performing a thermal nitridation process to nitride the oxide layer and performing a plasma nitridation process to nitride the oxide layer.

14. The semiconductor process according to claim 13, further comprising:
after performing the thermal nitridation process to nitride the oxide layer and performing the plasma nitridation process to nitride the oxide layer, performing an annealing process to the oxide layer.

15.-26. (canceled)
